(19) United States
(12) Patent Application Publication
(10) Pub. No.: US 2026/0043835 A1
(43) Pub. Date: Feb. 12, 2026

(54) LOW-TEMPERATURE CO-FIRED CERAMIC CURRENT SENSOR INTEGRATED WITHIN POWER MODULE

(71) Applicant: BOARD OF TRUSTEES OF THE UNIVERSITY OF ARKANSAS, Little Rock, AR (US)

(72) Inventors: Zhong Chen, Fayetteville, AR (US); H. Alan Mantooth, Fayetteville, AR (US); Pengyu Lai, Fayetteville, AR (US); Sudharsan Chinnaiyan, Fayetteville, AR (US)

(73) Assignee: BOARD OF TRUSTEES OF THE UNIVERSITY OF ARKANSAS, Little Rock, AR (US)

(21) Appl. No.: 19/297,033

(22) Filed: Aug. 12, 2025

Related U.S. Application Data
(60) Provisional application No. 63/682,289, filed on Aug. 12, 2024.

(51) Int. Cl. G01R 19/00; G01R 15/18; H05K 9/00

(52) U.S. Cl. CPC G01R 19/0046; G01R 15/18; H05K 9/0081

(57) ABSTRACT

A low-temperature co-fired ceramic (LTCC) current sensor integrated within the power module. The sensor includes a series of individual and stacked sheets, where such sheets may correspond to low-temperature co-fired ceramic sheets. The sensor further includes a power loop configured to provide power to the sensor. The sensor additionally includes a signal loop configured to sense power from the power loop. Furthermore, the sensor includes an electromagnetic interference shielding layer configured to protect circuitry of the sensor from external electromagnetic radiation. Such a sensor is capable of operating at high temperatures of approximately 250° C. Furthermore, since the sensor is designed on a high-temperature substrate material, the sensor is able to be easily integrated inside the power module.

### STATEMENT REGARDING FEDERALLY SPONSORED RESEARCH

This invention was made with government support under 1449548 awarded by the National Science Foundation. The government has certain rights in the invention.

### TECHNICAL FIELD

The present disclosure relates generally to power modules, and more particularly to a low-temperature co-fired ceramic (LTCC) current sensor integrated within the power module thereby enabling the power module to function at greater temperatures without necessitating the use of large cooling systems.

### BACKGROUND

A power module is a self-contained electronic component that integrates multiple power semiconductor devices, control circuitry, and passive components into a single package, enabling efficient power conversion and management in electronic systems. It simplifies power system design by combining functions that would otherwise require separate components leading to increased power density, improved reliability, and reduced design time.

Power modules are extensively utilized in power converters to decrease the dimensions of the power system and enhance the power density of the entire system. Modern power modules utilize wideband gap-based devices, such as silicon carbide (SiC) and gallium nitride (GaN). These materials offer inherent benefits, such as the ability to operate at high temperatures, faster switching speeds, a wider voltage range, and the capability to deliver power to various applications ranging from low voltage (e.g., 1.2 kV) to high voltage (e.g., 10 kV).

While power modules do decrease the size of power converter circuits, the inclusion of external gate drivers and control circuits still results in an overall increase in the size of the power system. Integrated power modules with embedded gate drivers are developed to streamline the system size.

The integrated gate drivers efficiently regulate the switches within the power modules resulting in reduced parasitics and enhanced switching performance of the power module. However, the efficient operation of the power system depends not only on the rapid switching of the power module, but also on accurate output measurement and effective system control. Contemporary power systems depend on external sensors to gauge the output of the power module. However, these sensors are larger and more cumbersome, resulting in an increase in the weight and dimensions of the power system.

Furthermore, precise monitoring and accurate control are necessary for power electronic modules operating at high temperatures and high densities. The sensor used in these situations must possess strong temperature resistance and deliver precise measurements regardless of the operating conditions. Unfortunately, the current sensors of power modules are not capable of meeting the demanding conditions of high temperature and density. For example, conventional power modules use sensors, which are heavier and bulkier for measuring the output current. Adding sensors external to the module increases the size of the power system and, consequently, increases the cost. In addition, all the existing sensors are not rated to operate at high temperatures, so the accuracy of the conventional sensors drops when the system is exposed to higher operating temperatures of approximately 250° C.

### SUMMARY

In one embodiment of the present disclosure, a sensor comprising a series of individual and stacked sheets. The sensor further comprises a power loop configured to provide power to the sensor. The sensor additionally comprises a signal loop configured to sense power from the power loop. Furthermore, the sensor comprises an electromagnetic interference shielding layer configured to protect circuitry of the sensor from external electromagnetic radiation.

In another embodiment of the present disclosure, a power module comprises one or more sensors, where each of the one or more sensors comprises a series of individual and stacked sheets. Furthermore, each sensor comprises a power loop configured to provide power to the sensor. Additionally, each sensor comprises a signal loop configured to sense power from the power loop. Furthermore, each sensor comprises an electromagnetic interference shielding layer configured to protect circuitry of the sensor from external electromagnetic radiation.

The foregoing has outlined rather generally the features and technical advantages of one or more embodiments of the present disclosure in order that the detailed description of the present disclosure that follows may be better understood. Additional features and advantages of the present disclosure will be described hereinafter which may form the subject of the claims of the present disclosure.

### BRIEF DESCRIPTION OF THE DRAWINGS

A better understanding of the present disclosure can be obtained when the following detailed description is considered in conjunction with the following drawings, in which:

FIG. 1 illustrates a LTCC-based current sensor to be integrated within a power module in accordance with an embodiment of the present disclosure;

FIG. 2 illustrates a power module with an integrated LTCC-based current sensor 100 in accordance with an embodiment of the present disclosure;

FIG. 3 illustrates a manufactured SiC power module, based on the power module of FIG. 2, designed for high-temperature operation, which includes the integrated LTCC gate driver substrates, in accordance with an embodiment of the present disclosure;

FIGS. 4A-4C illustrate the relationship between the drain voltage and the drain current of the power module of FIG. 2 at different temperatures and different time scales in accordance with an embodiment of the present disclosure;

FIG. 5 illustrates the closed-loop inverter-type power system in accordance with an embodiment of the present disclosure;

FIG. 6A illustrates the pads on the LTCC-based current sensor in accordance with an embodiment of the present invention;

FIG. 6B illustrates the bottom side of the LTCC-based current sensor in accordance with an embodiment of the present invention;

FIGS. 7A-7B illustrate the measurement results from the LTCC-based current sensor for temperatures ranging from 25° C. to 200° C. in accordance with an embodiment of the present disclosure; and

FIG. 8 depicts a model of a high-temperature power module, which includes two integrated LTCC-based current sensors, in accordance with an embodiment of the present disclosure.

### DETAILED DESCRIPTION

As stated above, power modules are extensively utilized in power converters to decrease the dimensions of the power system and enhance the power density of the entire system. Modern power modules utilize wideband gap-based devices, such as silicon carbide (SiC) and gallium nitride (GaN). These materials offer inherent benefits, such as the ability to operate at high temperatures, faster switching speeds, a wider voltage range, and the capability to deliver power to various applications ranging from low voltage (e.g., 1.2 kV) to high voltage (e.g., 10 kV).

While power modules do decrease the size of power converter circuits, the inclusion of external gate drivers and control circuits still results in an overall increase in the size of the power system. Integrated power modules with embedded gate drivers are developed to streamline the system size.

The integrated gate drivers efficiently regulate the switches within the power modules resulting in reduced parasitics and enhanced switching performance of the power module. However, the efficient operation of the power system depends not only on the rapid switching of the power module, but also on accurate output measurement and effective system control. Contemporary power systems depend on external sensors to gauge the output of the power module. However, these sensors are larger and more cumbersome, resulting in an increase in the weight and dimensions of the power system.

Furthermore, precise monitoring and accurate control are necessary for power electronic modules operating at high temperatures and high densities. The sensor used in these situations must possess strong temperature resistance and deliver precise measurements regardless of the operating conditions. Unfortunately, the current sensors of power modules are not capable of meeting the demanding conditions of high temperature and density. For example, conventional power modules use sensors, which are heavier and bulkier for measuring the output current. Adding sensors external to the module increases the size of the power system and, consequently, increases the cost. In addition, all the existing sensors are not rated to operate at high temperatures, so the accuracy of the conventional sensors drops when the system is exposed to higher operating temperatures of approximately 250° C.

The embodiments of the present disclosure provide a novel power module with integrated LTCC (low-temperature co-fired ceramic)-based current sensors which is capable of operating in a high-temperature environment of approximately 250° C. Precise monitoring and accurate control are necessary for power electronic modules operating at high temperatures and high densities. The sensor used in these situations must possess strong temperature resistance and deliver precise measurements regardless of the operating conditions. To meet the demanding conditions of high temperature and density, power modules and their components must be designed to function and endure high temperatures, while also being able to be integrated within the power module. The embodiments of the present disclosure provide a LTCC-based current sensor that is capable of operating in a high-temperature environment of approximately 250° C. while being able to be integrated within the power module.

In one embodiment, the LTCC-based current sensor of the present disclosure is manufactured through the process of stacking and laminating individual LTCC sheets, followed by co-firing in an atmosphere with a temperature of around 850° C. The final substrate is more robust and has a high temperature resistance capability of around 400° C. This substrate possesses the adaptability to be seamlessly included within the power module and can be soldered directly within it.

High-temperature power modules have a huge impact on power electronic technologies, such as electric vehicles, space vehicle design, and deep oil and gas explorations. All these applications require the system to be more efficient, have a higher power density, and be easy to control. Wideband gap devices enable the power module to operate at a temperature of about 250° C. However, building the power system to operate at 250° C. necessitates operating all the components and sensor elements in a high-temperature environment.

Integrating commercially available sensors into high-temperature power modules will limit the operating temperature of the module as these sensors usually have an operating temperature limit of 125° C. High temperatures strongly affect the reliability of commercially available sensors as well as their performance in the presence of environmental factors, such as temperature, humidity, and corrosion. These conditions also influence the measured data and may result in power system failure. In one embodiment, the designed LTCC-based current sensors of the present disclosure feature a unique coil design and can maintain output accuracy at higher operating temperatures. In addition, the design of the LTCC-based current sensors of the present disclosure fits inside the power module to achieve higher power density in compact power system environments.

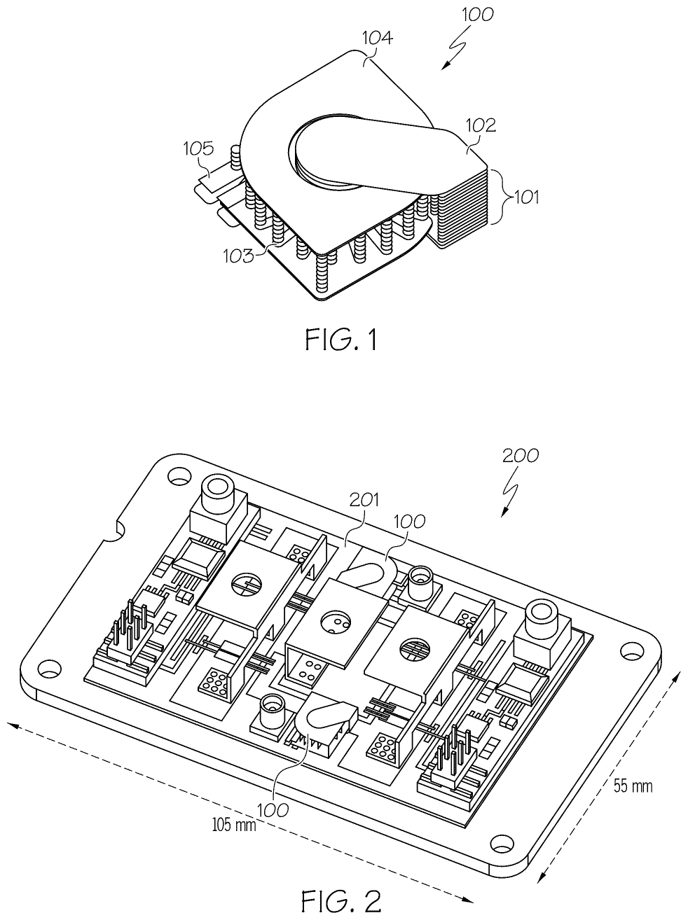

In one embodiment, the LTCC-based current sensor of the present disclosure includes eighteen individual LTCC sheets stacked together to form the complete structure. Traces and vias split the design of the sensor across eighteen layers, which are then stacked to obtain the 3D model of the sensor. In one embodiment, the 3D design has three distinct features, such as a power loop, a signal loop, and an EMI (electromagnetic interference) shielding layer as discussed further below in connection with FIG. 1.

As also discussed further below, the inclusion of the LTCC-based current sensor inside the power module eliminates the need for an external bulkier sensor thereby allowing for precise monitoring and control of the power system in high-temperature environments.

Referring now to the Figures in detail, FIG. 1 illustrates a LTCC-based current sensor 100 to be integrated within a power module in accordance with an embodiment of the present disclosure.

As illustrated in FIG. 1, LTCC-based current sensor 100 includes a series of individual and stacked sheets 101. It is noted that LTCC-based current sensor 100 may include any number of individua sheets 101 stacked together to form a complete structure, such as including at least 10 sheets, 15 sheets or 18 sheets. In one embodiment, sheets 101 include low-temperature co-fired ceramic (LTCC) sheets.

Furthermore, FIG. 1 illustrates LTCC-based current sensor 100 including a power loop 102. Power loop 102, as used herein, refers to the closed electrical circuit that proves power to the sensor and transmits the measured current signal.

Additionally, FIG. 1 illustrates LTCC-based current sensor 100 including a signal loop 103. Signal loop 103, as used herein, refers to the electrical path formed within the sensor where the electrical current to be measured induces a measurable effect that is then converted into a usable signal. In one embodiment, signal loop 103 is operable to sense the AC power from power loop 102 and integrate the AC power to obtain a measured output.

In one embodiment, power loop 102 detects the flow of output AC power from the power module and signal loop 103 integrates it to obtain the measured output.

Furthermore, FIG. 1 illustrates LTCC-based current sensor 100 including an electromagnetic interference (EMI) shielding layer 104. In one embodiment, EMI shielding layer 104 is configured to protect the sensor's sensitive circuitry from external electromagnetic radiation and prevent its internal signals from interfering with neighboring components. In one embodiment, EMI shield layer 104 protects signal loop 103 and power loop 102 from external noise sources.

Additionally, in one embodiment, LTCC-based current sensor 100 includes a bottom pad 105 operable to interface with a power module component. In one embodiment, bottom pad 105 is operable to facilitate the measurement of an output from signal loop 103 by an external circuitry.

Referring now to FIG. 2, FIG. 2 illustrates a power module 200 with an integrated LTCC-based current sensor 100 in accordance with an embodiment of the present disclosure.

As shown in FIG. 2, LTCC-based current sensor 100 is a component of power module 200. In one embodiment, LTCC-based current sensor 100 is integrated into the power module's direct bonded copper (DBC) substrate 201.

Furthermore, as illustrated in FIG. 2, in one embodiment, the dimensions of power module 200 include a length of 105 mm and a width of 55 mm.

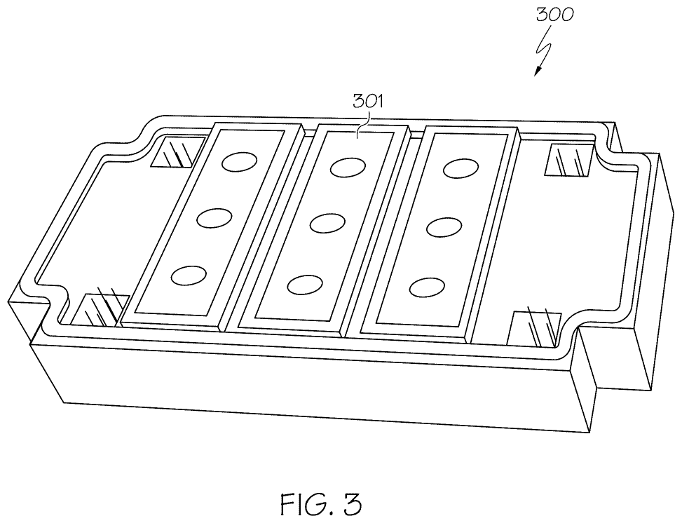

As discussed further herein, the working of the high-temperature integrated power module with built-in optical isolation for temperatures ranging from 25° C. to 200° C. has been demonstrated. FIG. 3 illustrates a manufactured SiC power module 300, based on power module 200 of FIG. 2, designed for high-temperature operation, which includes integrated LTCC gate driver substrates, in accordance with an embodiment of the present disclosure. The module design features reduced parasitic loop and integrated gate driver substrates capable of withstanding thermal cycling with little thermal expansion. Furthermore, FIG. 3 illustrates that SiC power module 300 includes one or more power terminals 301.

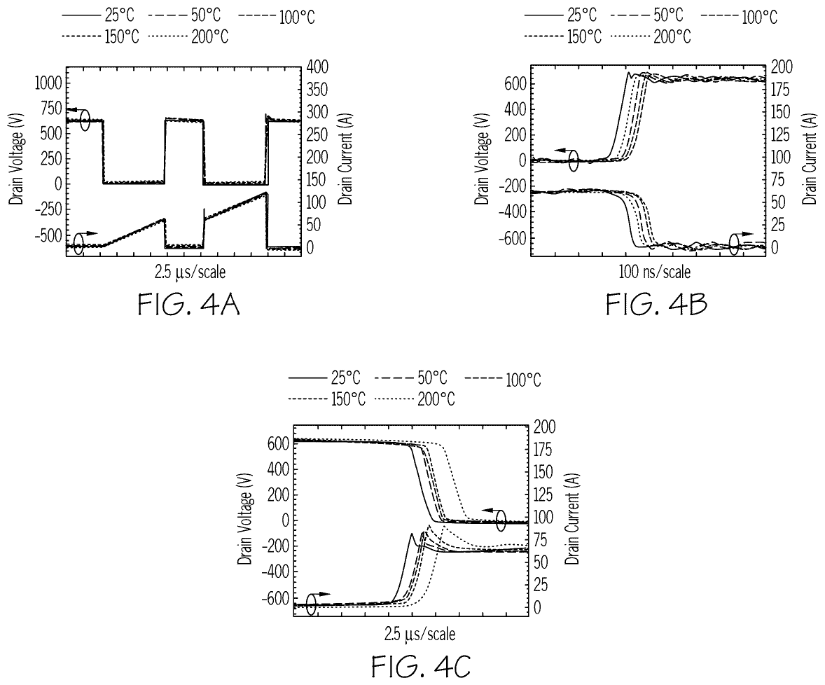

The dynamic performance of power module 200 has been analyzed, where the results of such an analysis are illustrated in FIGS. 4A-4C.

FIGS. 4A-4C illustrate the relationship between the drain voltage and the drain current of power module 200 of FIG. 2 at different temperatures and different time scales in accordance with an embodiment of the present disclosure.

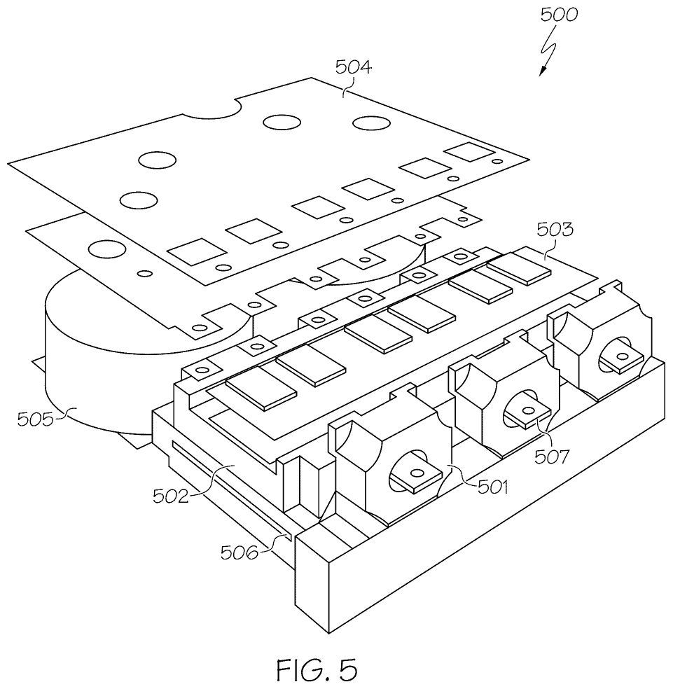

Referring now to FIG. 5, FIG. 5 illustrates the closed-loop inverter-type power system 500 in accordance with an embodiment of the present disclosure.

In one embodiment, system 500 includes three additional current sensors 501 (e.g., LTCC-based current sensor) located outside power module 502 (e.g., power module 200), along with an external gate driver 503 arrangement, which controls the switching, such as by acting as an interface between the low-power control circuit (e.g., generates the control signals) and the high-power switches.

Furthermore, as illustrated in FIG. 5, system 500 includes a laminated DC busbar 504, which is an engineered power distribution component consisting of multiple layers of conductive metal (e.g., copper, aluminum) separated by thin layers of dielectric (insulating) material.

Additionally, as illustrated in FIG. 5, system 500 includes DC link capacitors 505, which act as an energy buffer and filter between the DC input and the inverter stage.

Furthermore, in one embodiment, system 500 includes cold plate 506 and AC busbar 507. In one embodiment, cold plate 506 is responsible for efficiently removing heat from the power electronics, such as Insulated Gate Bipolar Transistors (IGBTs) and other semiconductors within the inverter. In one embodiment, AC busbar 507 serves as a central point for the distribution and collection of alternating current (AC) electricity.

In order to streamline the size of the traditional power system and enhance power density at elevated temperatures, in one embodiment, the current sensor is incorporated within the power module

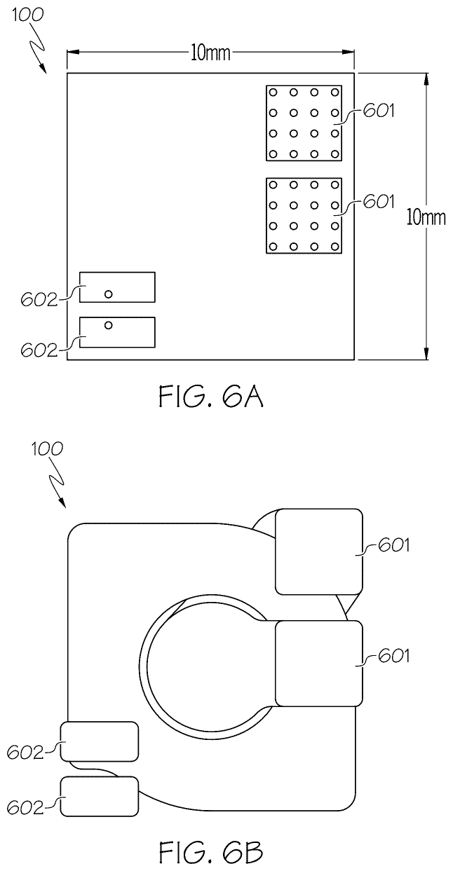

Referring now to FIGS. 6A-6B, FIG. 6A illustrates the pads on LTCC-based current sensor 100 in accordance with an embodiment of the present invention. FIG. 6B illustrates the bottom side of LTCC-based current sensor 100 in accordance with an embodiment of the present invention.

As illustrated in FIG. 6A, LTCC-based current sensor 100 has dimensions of approximately 10×10 mm thereby enabling LTCC-based current sensor 100 to be conveniently installed within a power module, such as power module 200 of FIG. 2.

Furthermore, FIGS. 6A-6B illustrate LTCC-based current sensor 100 including power pads 601, which are exposed metal areas on the bottom of LTCC-based current sensor 100 designed for heat dissipation.

In one embodiment, LTCC-based current sensor 100 includes a power coil (e.g., coil of an inductor). In one embodiment, the power coil functions as a transformer by converting low voltage into high voltage. In one embodiment, power pads 601 dissipate heat generated by the power coil.

Additionally, FIGS. 6A-6B illustrate LTCC-based current sensor 100 including signal pads 602, which are exposed metal areas on the LTCC substrate used for making electrical connections. In one embodiment, signal pads 602 are used for transmitting or receiving signals.

In one embodiment, LTCC-based current sensor 100 includes a sensor coil for sensing. In one embodiment, the sensor coil is an active element that interacts with the environment (e.g., magnetic fields, proximity) and produces a measurable signal (e.g., inductance change). Such a signal is then conveyed from the sensor coil through signal pad 702 to the measuring electronics or further processing stages.

In one embodiment, pads 601, 602 of LTCC-based current sensor 100 conveniently interface with the direct bonded copper (DBC) substrate of the power module (e.g., power module 200). This facilitates the passage of electric current through the power loop (e.g., power loop 102) of LTCC-based current sensor 100.

In one embodiment, LTCC-based current sensor 100 operates based on the idea of mutual inductance. When an electric current that changes over time passes through power loop 102 of LTCC-based current sensor 100, it generates a magnetic field, which in turn produces an electric voltage in signal loop 103. The voltage recorded is directly proportional to the current passing through the power circuit.

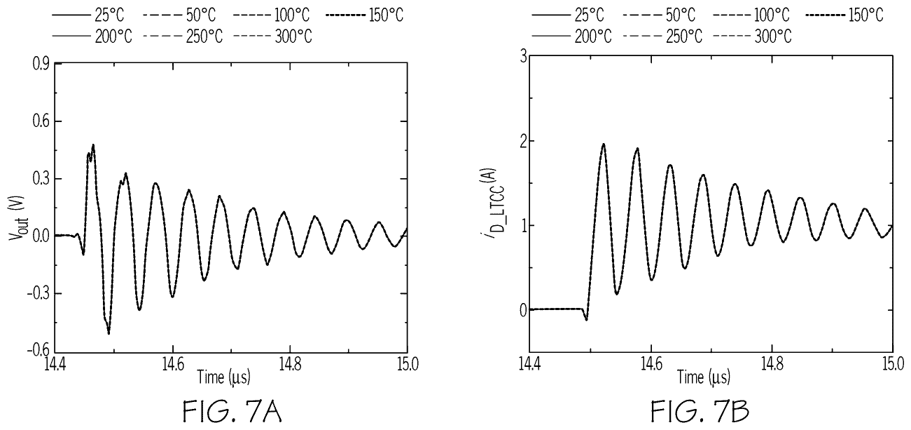

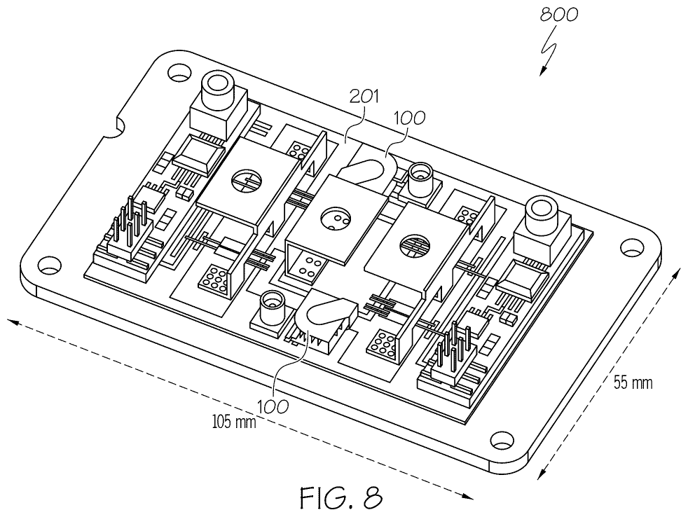

FIGS. 7A-7B illustrate the measurement results from LTCC-based current sensor 100 for temperatures ranging from 25° C. to 200° C. in accordance with an embodiment of the present disclosure. That is, FIGS. 7A-7B displays the performance of LTCC-based current sensor 100 that was constructed, tested using discrete devices, and evaluated at temperatures ranging from 25° C. to 250° C. For example, FIG. 7A illustrates the voltage measurement of LTCC-based current sensor 100 during the temperature range from 25° C. to 200° C. FIG. 7B illustrates the calculated current of LTCC-based current sensor 100 during the temperature range from 25° C. to 200° C. The preliminary evaluation of the discrete switches demonstrates the capability of LTCC-based current sensor 100 to sense current.

In one embodiment, LTCC-based current sensor 100 operates in tandem with power modules on direct bonded copper (DBC) substrate 201. As a result, in one embodiment, LTCC-based current sensor 100 is integrated inside the power loop of the power module (e.g., power module 200). FIG. 8 depicts a model of a high-temperature power module 800, which includes two integrated LTCC-based current sensors 100, in accordance with an embodiment of the present disclosure. The dimensions of power module 800 (e.g., length of 105 mm and a width of 55 mm) are identical to those of the high-temperature power module depicted in FIG. 3. However, it possesses the additional benefit of accurately measuring current at high temperatures (e.g., 250° C.).

Furthermore, FIG. 8 illustrates power module 800 with the high-temperature integrated LTCC-based current sensor 100 incorporated into the power module's DBC substrate 201. As a result, power module 800 has the benefit of closely monitoring the current straight from the power module's DBC substrate 201 in high-temperature settings of up to 250° C. The inclusion of the LTCC-based current sensor (e.g., LTCC-based current sensor 100) inside the power module eliminates the need for an external bulkier sensor allowing for precise monitoring and control of the power system in high-temperature environments.

By implementing this sensor concept of the present disclosure, power systems can be downsized while implementing wideband gap devices in high-temperature power electronics.

As previously discussed, conventional power modules use sensors, which are heavier and bulkier for measuring the output current. Adding sensors external to the module increases the size of the power system and, consequently, increases the cost. In addition, all the existing sensors are not rated to operate at high temperatures so the accuracy of the conventional sensors drops when the system is exposed to higher operating temperatures of approximately 250° C. Embodiments of the present disclosure are directed to a novel high-temperature current sensor capable of operating at high temperatures of approximately 250° C. The sensor is designed on a high-temperature substrate material, which allows for easier integration inside the power module.

Advantages include higher operating temperatures compared to conventional sensors, increased power density due to direct integration of the sensor inside the power module substrate, and precise measurement and ease of control. Applications include use in high density power modules, DC and AC power control, power supply regulation, and high temperature sensors.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1. A sensor, the sensor comprising:
a series of individual and stacked sheets;
a power loop configured to provide power to said sensor;
a signal loop configured to sense power from said power loop; and
an electromagnetic interference shielding layer configured to protect circuitry of said sensor from external electromagnetic radiation.

2. The sensor as recited in claim 1, wherein said series of individual and stacked sheets comprises 18 sheets.

3. The sensor as recited in claim 1, wherein said series of individual and stacked sheets comprises low-temperature co-fired ceramic sheets.

4. The sensor as recited in claim 1, wherein said power loop detects a flow of output AC power from a power module.

5. The sensor as recited in claim 4, wherein said signal loop integrates said detected AC power to obtain a measured output.

6. The sensor as recited in claim 1, wherein said signal loop is operable to sense AC power from said power loop and integrate said AC power to obtain a measured output.

7. The sensor as recited in claim 1, wherein said electromagnetic interference shielding layer protects said signal loop and said power loop from external noise sources.

8. The sensor as recited in claim 1 further comprising:
a bottom pad operable to interface with a power module component.

9. The sensor as recited in claim 8, wherein said bottom pad is further operable to facilitate a measurement of an output from said signal loop by an external circuitry.

10. The sensor as recited in claim 1, wherein said sensor is a current sensor.

11. The sensor as recited in claim 1, wherein said sensor is a low-temperature co-fired ceramic current sensor.

12. The sensor as recited in claim 1, wherein said sensor is operable to perform at a high-temperature environment of approximately 250° C.

13. The sensor as recited in claim 1, wherein said sensor is a component of a power module.

14. The sensor as recited in claim 1, wherein said sensor is integrated into a power module's direct bonded copper substrate.

15. A power module, comprising:
one or more sensors, wherein each of said one or more sensors comprises:
a series of individual and stacked sheets;
a power loop configured to provide power to said sensor;
a signal loop configured to sense power from said power loop; and
an electromagnetic interference shielding layer configured to protect circuitry of said sensor from external electromagnetic radiation.

16. The power module as recited in claim 15, wherein said series of individual and stacked sheets comprises 18 sheets.

17. The power module as recited in claim 15, wherein said series of individual and stacked sheets comprises low-temperature co-fired ceramic sheets.

18. The power module as recited in claim 15, wherein said sensor is a current sensor.

19. The power module as recited in claim 15, wherein said sensor is a low-temperature co-fired ceramic current sensor.

20. The power module as recited in claim 15, wherein said sensor is integrated into a direct bonded copper substrate of said power module.
